(19) United States
(12) Patent Application Publication
(10) Pub. No.: US 2014/0167092 A1
(43) Pub. Date: Jun. 19, 2014

(54) OPTOELECTRONIC ASSEMBLY AND METHOD FOR PRODUCING AN OPTOELECTRONIC ASSEMBLY

(71) Applicants: Christian Gärtner, Neutraubling (DE); Ales Markytan, Regensburg-Burgweinting (DE)

(72) Inventors: Christian Gärtner, Neutraubling (DE); Ales Markytan, Regensburg-Burgweinting (DE)

(73) Assignee: OSRAM Opto Semiconductors GmbH, Regensburg (DE)

(21) Appl. No.: 14/236,676

(22) PCT Filed: Jul. 4, 2012
(86) PCT No.: PCT/EP2012/062974

§ 371 Date: Feb. 3, 2014

(30) Foreign Application Priority Data
Aug. 4, 2011 (DE) 10 2011 080 458.7

(51) Int. Cl. H01L 33/52; H01L 33/60

(52) U.S. Cl. CPC H01L 33/52; H01L 33/60
USPC 257/98

(57) ABSTRACT

An optoelectronic assembly includes a carrier, an optoelectronic component arranged on the carrier, wherein the optoelectronic component includes a substrate and a light-emitting layer arranged on the substrate, and a light-reflecting first encapsulation at least locally covers a region of the carrier surrounding the optoelectronic component and side surfaces of the optoelectronic component.

### TECHNICAL FIELD

This disclosure relates to an optoelectronic assembly and to a method of producing such an assembly.

### BACKGROUND

Optoelectronic assemblies comprise at least one optoelectronic component. The term “light-emitting diode (LED)” is synonymous with the term optoelectronic component. The optoelectronic component may emit electromagnetic radiation. The optoelectronic component is arranged on a carrier. The carrier is necessary for mechanical and electrical contacting of the optoelectronic component. For example, a printed circuit board (PCB) may be used as the carrier. Carriers generally absorb at least a part of the incident electromagnetic radiation in the visible spectral range. For this reason, a part of the electromagnetic radiation emitted by the optoelectronic component is absorbed by the carrier. The efficiency of the optoelectronic assembly is reduced by these absorption losses.

There is thus a need to provide an optoelectronic assembly in which the absorption losses are reduced.

### SUMMARY

We provide an optoelectronic assembly including a carrier, an optoelectronic component arranged on the carrier, wherein the optoelectronic component includes a substrate and a light-emitting layer arranged on the substrate, and a light-reflecting first encapsulation at least locally covers a region of the carrier surrounding the optoelectronic component and side surfaces of the optoelectronic component.

We also provide an optoelectronic assembly including a carrier, an optoelectronic component arranged on the carrier, wherein the optoelectronic component includes a substrate and a light-emitting layer arranged on the substrate, a light-reflecting first encapsulation at least locally covering a region of the carrier surrounding the optoelectronic component and side surface of the optoelectronic component, and a second encapsulation applied at least locally on the first encapsulation, wherein the second encapsulation ends flush, within the scope of manufacturing tolerance, with an edge of the light-emitting layer facing away from the substrate.

We further provide a lighting device having the optoelectronic assembly including a carrier, an optoelectronic component arranged on the carrier, wherein the optoelectronic component includes a substrate and a light-emitting layer arranged on the substrate, and a light-reflecting first encapsulation at least locally covers a region of the carrier surrounding the optoelectronic component and side surfaces of the optoelectronic component, wherein a second optical unit forwards light emerging from the optoelectronic assembly.

### BRIEF DESCRIPTION OF THE DRAWINGS

FIGS. 1 and 2 show known optoelectronic assemblies in sectional view.

FIGS. 3 and 4 show optoelectronic assemblies having a single optoelectronic component in sectional view.

FIGS. 5-10 show optoelectronic assemblies having two optoelectronic components in sectional view.

FIGS. 11-15 show optoelectronic components in sectional view.

FIGS. 16-18 show optoelectronic assemblies having two optoelectronic components in sectional view.

FIGS. 19-21 show optoelectronic assemblies having a multiplicity of optoelectronic components in plan view.

FIGS. 22 and 23 show the optoelectronic assembly of FIG. 20 in sectional view.

FIGS. 24 and 25 show lighting devices in sectional view.

### LIST OF REFERENCES

100 optoelectronic assembly
102 carrier
104 optoelectronic component=LED
106 substrate
108 light-emitting layer
110 first encapsulation
112 side surface of the optoelectronic component
114 thickness of the substrate
116 scattering particles
118 second encapsulation
120 luminescent particles
122 light-emitting semiconductor chip
124 third encapsulation
126 fourth encapsulation
128 edge of the optoelectronic assembly
130 vertical
132 emission angle
134 light emitted by LED
136 LED which emits amber light
138 LED which emits mint light
140 height
142 width
144 section axis
200 lighting device
202 secondary optical unit
302 conversion lamina
304 clear lens
306 contacts
308 vias
310 bond pads
312 bonding wire
314 contact pad

### DETAILED DESCRIPTION

We provide an optoelectronic assembly having a carrier and an optoelectronic component arranged on the carrier. The optoelectronic component comprises a substrate and a light-emitting layer. The light-emitting layer is applied on the substrate. The optoelectronic assembly comprises a light-reflecting first encapsulation which at least locally covers the region of the carrier surrounding the optoelectronic component and the side surfaces of the optoelectronic component. By the use of the light-reflecting first encapsulation, the absorption losses are reduced and the efficiency of the optoelectronic assembly is increased.

Preferably, the carrier comprises one of the following elements:
a printed circuit board (PCB),
a ceramic substrate,
a metal core circuit board,
a leadframe or
a plastic laminate.

Preferably, the substrate of the optoelectronic component comprises one of the following materials:
aluminum nitride (AlN),
aluminum oxide (Al₂O₃) or
leadframe, in particular comprising copper, with plastic or silicone injection-molded around it.

Substrates of optoelectronic components at least partially absorb incident electromagnetic radiation in the visible spectral range.

Preferably, the light-emitting layer comprises a semiconductor chip. The semiconductor chip may be at least locally surrounded by an encapsulation, which is referred to as “a third encapsulation.” The encapsulation material may be clear. Alternatively, the encapsulation material may be filled with luminescent particles. Alternatively, the encapsulation material may be filled with scattering particles. Alternatively, the encapsulation material may be filled with both luminescent particles and with scattering particles.

The semiconductor chips comprise at least one active zone which emits electromagnetic radiation. The active zones may be pn junctions, a double heterostructure, multiple quantum well structure (MQW) or single quantum well structure (SQW). A quantum well structure means: quantum wells (3-dim), quantum wires (2-dim) and quantum dots (1-dim).

Preferably, the semiconductor chip is based on a III-V compound semiconductor material. The semiconductor chip may comprise indium gallium nitride (InGaN). These semiconductor chips may emit electromagnetic radiation of from the UV range to the green range, in particular about 400 nm to about 570 nm. Alternatively preferably, the semiconductor chip may comprise indium gallium aluminum phosphide (InGaAlP). These semiconductor chips may emit electromagnetic radiation of from the red range to the green range, in particular about 570 nm to about 700 nm.

Preferably, the semiconductor chip may be a wire-contacted semiconductor chip.

Alternatively or additionally, the semiconductor chip may be configured as a flip-chip. Flip-chips are advantageous since the shadowing by the bonding wire is eliminated and no active surface area is lost due to the bond pad on the semiconductor chip.

Preferably, the semiconductor chip may be formed as a surface emitter, in particular as a so-called “thin-film chip.” Thin-film chips are known, for example, from WO2005081319A1. If, during production of the semiconductor chip, in particular of a semiconductor chip having a mirror layer containing metal, the growth substrate of the semiconductor layer sequence is removed, then such semiconductor chips produced with removal of the growth substrate are also referred to as a thin-film chip. The radiation-emitting semiconductor chip may comprise a stack of different III-V nitride semiconductor layers, in particular gallium nitride layers. The thin-film chip is configured without a radiation-absorbing substrate, and a reflector is applied directly on the GaN semiconductor body comprising the stack of different III-V nitride semiconductor layers.

Preferably, the semiconductor chip may be formed as a so-called “UX-3 chip” (internal product designation of OSRAM). This UX-3 chip is known from DE102007022947A1. An optoelectronic semiconductor body is described therein having a semiconductor layer sequence comprising an active layer, and first and second electrical connection layers. The semiconductor layer is intended to emit of electromagnetic radiation from a front side. The first and second electrical connection layers are arranged on a back side opposite the front side. They are electrically insulated from one another by a separating layer. The first electrical connection layer, the second electrical connection layer and the separating layer may laterally overlap. A subregion of the second electrical connection layer extends from the back side through a hole in the active layer in the direction of the front side. An advantage of the UX-3 chip is that, in contrast to the thin-film chip, no metal is any longer arranged on the front side of the semiconductor layer sequence. Absorption losses are thereby avoided. The subject matter of WO2005081319A1, DE102006015788A1 and DE102007022947A1 are hereby incorporated by reference into this disclosure.

Preferably, the semiconductor chip may be formed as a volume emitter, in particular as a sapphire chip. The sapphire volume emitter is known, for example, from DE102006015788A1. In this case, sapphire may be used as the growth substrate for the semiconductor layer sequence. In contrast to the thin-film chip, in the case of the sapphire volume emitter, the growth substrate is not removed from the semiconductor layer sequence at the end of the production process. The (growth) substrate is radiation-transmissive for the radiation generated in the active zone. This facilitates the output of radiation from the semiconductor chip through the substrate. The semiconductor chip is therefore formed as a volume emitter. In the case of a volume emitter, in contrast to a surface emitter, a considerable radiation fraction is also output from the semiconductor chip via the substrate. In the case of a volume emitter, the surface luminous density on the output surfaces of the semiconductor chip is reduced compared with a surface emitter.

Preferably, the light-reflecting first encapsulation has a minimum height above the carrier which corresponds to the thickness of the substrate. This is particularly advantageous since the first encapsulation fully covers the light-absorbing carrier and the light-absorbing substrate of the optoelectronic component. The absorption losses due to the carrier and the substrate are minimized.

Preferably, the light-reflecting first encapsulation has a minimum height above the carrier of 80 μm. Particularly preferably, the light-reflecting first encapsulation has a height of more than 200 μm.

Preferably, the light-reflecting first encapsulation comprises a matrix material filled with scattering particles. The scattering particles are present in a concentration of 5 percent by weight to 60 percent by weight. The matrix material may comprise silicone, epoxy resin or hybrid materials. The scattering particles may comprise titanium dioxide (TiO₂), aluminum oxide (Al₂O₃) or zirconium oxide (ZrO).

Preferably, a second encapsulation may be applied at least locally on the first encapsulation. This is particularly advantageous since the optical properties of the optoelectronic assembly can be modulated by the second encapsulation.

Preferably, the second encapsulation may end flush, within the scope of a manufacturing tolerance, with the edge of the light-emitting layer facing away from the substrate. This is advantageous since it achieves the effect that electromagnetic radiation emerging laterally from the light-emitting layer always passes through the second encapsulation first before it emerges from the optoelectronic assembly. It is furthermore advantageous since the overall height of the optoelectronic component is reduced compared to the overall height of an optoelectronic component having a lens.

Preferably, the second encapsulation may comprise a transparent, unfilled matrix material. This is advantageous since light from the light-emitting layer, which enters the second encapsulation, is at least partially mixed before it emerges from the second encapsulation.

The luminous density and the output efficiency can furthermore also be adjusted by the refractive index of the first encapsulation and/or of the second encapsulation. The higher the refractive index of the encapsulation is, the more light is totally reflected at the encapsulation/air interface. The more light is totally reflected, the better the light is distributed in the encapsulation-filled gap between the optoelectronic components.

The refractive index of the second encapsulation may be different from the refractive index of the third encapsulation, which covers the semiconductor chip in the light-emitting layer. The second encapsulation and the light-emitting layer are in direct optical contact. The luminous density and the output efficiency can be adjusted by suitable selection of the refractive index of the second and third encapsulations.

Preferably, the second encapsulation may comprise a matrix material filled with scattering particles. The scattering particles are present in a concentration of 0.001 percent by weight to 1 percent by weight. The use of scattering particles in the second encapsulation is particularly advantageous since, in this way, light emitted from the side surfaces of the light-emitting layer is mixed before it leaves the optoelectronic assembly. The concentration of the scattering particles may be adjusted within the aforementioned range. In the case of low concentrations, the light is scattered in the second encapsulation without being fully reflected. The effect achieved by the above concentration of the scattering particles, which is low compared to the concentration of the scattering particles in the first encapsulation, is that the light is output over the entire surface of the second encapsulation.

Preferably, the second encapsulation may comprise a matrix material filled with luminescent particles. This is particularly advantageous since the luminescent particles in the second encapsulation convert a part of the radiation emerging laterally from the light-emitting layer in the second encapsulation. Converted light therefore emerges not only from the surface of the light-emitting layer, but also from the region which is covered by the second encapsulation. The perturbing contrast between the light-emitting layer and the region which surrounds the light-emitting layer is reduced. Contrast refers both to the brightness contrast and to the color contrast.

The luminescent particles may be present in the second encapsulation in a concentration of 4 percent by weight to 30 percent by weight. With the concentration of the luminescent particles, it is possible to adjust the fraction of the light, input into the second encapsulation from the light-emitting layer, which is converted. The luminescent particles comprise at least one of the following materials:
lanthanum-doped yttrium oxide (Y₂O₃—La₂O₃),
yttrium aluminum garnet (Y₃Al₅O₁₂),
dysprosium oxide (Dy₂O₃),
aluminum oxynitride (Al₂₃O₂₇N₅) or
aluminum nitride (AlN).

Preferably, at least one further optoelectronic component may be arranged on the carrier. Optoelectronic assemblies having a plurality of optoelectronic components are advantageous since the luminous power can be scaled virtually as desired. Up to several hundred optoelectronic components may be combined in an optoelectronic assembly.

Preferably, the light-reflecting first encapsulation with the scattering particles embedded therein fully covers the carrier and fully covers the side surfaces of the substrate of the optoelectronic components. The first encapsulation thus forms a diffusely reflecting material so that the reflectivity of the regions between the optoelectronic components and around the optoelectronic components is increased. This first encapsulation also achieves the effect that at least a part of the light which is emitted from the light-emitting layer at angles of more than about 87° with respect to the vertical are scattered back into the optoelectronic component. A part of this back-scattered light can then leave the optoelectronic component at angles of less than 85° with respect to the vertical. The undesired absorption of the light by neighboring optoelectronic components or by the carrier is reduced.

Preferably, the second encapsulation with the luminescent particles embedded therein covers both the first encapsulation and the side surfaces of the light-emitting layer of the multiplicity of optoelectronic components. This is advantageous since, in this way, the regions between the optoelectronic components also emit electromagnetic radiation. The radiation emitted from the intermediate regions is composed of the radiation input into the second encapsulation from the side surfaces of the light-emitting layer and of the radiation converted in the luminescent particles. The homogeneity of the luminous density of the optoelectronic assembly is increased.

Alternatively, the effect achieved by the slightly diffuse second encapsulation (0.001 percent by weight to 1 percent by weight of scattering particles in the matrix material) is that the light emitted by the light-emitting layer on the side surfaces is distributed uniformly over the intermediate spaces between the optoelectronic components. In other words, the light is output over the entire surface of the optoelectronic assembly.

Alternatively, the second encapsulation comprises both scattering particles and luminescent particles. This is particularly advantageous since the advantages of a second encapsulation having only scattering particles or having only luminescent particles are combined.

Advantageously, formation of multiple shadows or color shadows decreases as a result of use of a first and/or second encapsulation between the optoelectronic components.

Multiple shadows become visible when the light of a plurality of mutually separated optoelectronic components of one color is imaged by reflectors.

Color shadows become visible when the light of a plurality of mutually separated optoelectronic components of different colors is imaged by reflectors.

Preferably, the distance between neighboring optoelectronic components is 0.1 mm to 1 mm, preferably 0.2 mm to 0.5 mm. The smaller the distance, the less pronounced the visibility of the multiple shadows or color shadows. For process technology reasons, however, the distance should not be less than 0.1 mm. These process technology reasons may be tolerances in the component dimension, positioning accuracy, temperature management or the design of the optics.

Different examples comprise a lighting device which combines an optoelectronic assembly with a secondary optical unit. The optoelectronic assembly may be formed according to one of the examples above. The combination of an optoelectronic assembly and a secondary optical unit is advantageous since, in this way, light emerging from the optoelectronic assembly can be forwarded and/or imaged.

Preferably in the lighting device, the secondary optical unit comprises at least one of the following elements:
a light guide,
a scattering disk,
a lens or
a reflector.

Use of a light guide is particularly advantageous since, in this way, light can be forwarded virtually loss-free over large distances. Use of a scattering disk is advantageous since, in this way, the light emerging from the optoelectronic assembly can be mixed even more strongly. Use of a lens is advantageous since, in this way, the light emerging from the optoelectronic assembly can be concentrated. Use of a reflector is advantageous since the light emerging from the optoelectronic assembly can be focused in the forward direction. In particular, light emitted from the optoelectronic components at angles of more than 90° with respect to the vertical can be reflected forward and is therefore not lost.

Different examples comprise a method of producing an optoelectronic assembly, having the following steps. First, a carrier is provided. At least one optoelectronic component is arranged on the carrier. A light-reflecting first encapsulation is applied onto the region of the carrier surrounding the optoelectronic component. The first encapsulation is applied such that it furthermore covers the side surfaces of the optoelectronic component at least locally.

Preferably, after the application of the first encapsulation, a second encapsulation is applied onto the first encapsulation.

Different examples will now be explained in more detail below with the aid of the drawings. Elements which are the same or of the same type, or which have the same effect, are provided with the same references in the figures. The figures and the size proportions of the elements represented in the figures with respect to one another are not to be regarded as true to scale. Rather, individual elements may be represented exaggeratedly large or with reduced size for better representability and for better comprehensibility.

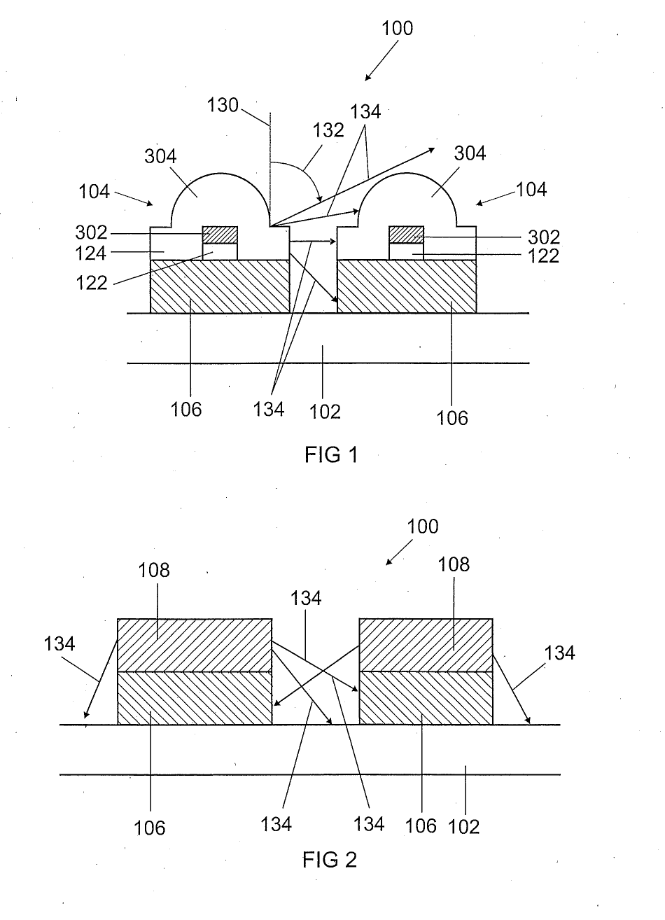

FIG. 1 shows an example of a known optoelectronic assembly 100 in sectional view. Two optoelectronic components 104 are shown, which are arranged on a light-absorbing carrier 102. The optoelectronic component comprises a light-absorbing substrate 106. A light-emitting semiconductor chip 122 is arranged on the substrate 106. The semiconductor chip 122 is covered by a converter lamina 302. The semiconductor chip 122 and the converter lamina 302 are encapsulated in a third encapsulation 124. A clear lens 304 is arranged on the third encapsulation 124. The third encapsulation 124 and the clear lens 304 comprise silicone. The application spacing between the two optoelectronic components may be about 0.5 mm. Light emitted at angles 132 of more than about 87° with respect to the vertical 130 can be absorbed by the substrate 106 and by the clear lens 304 of the neighboring optoelectronic component 104, as well as by the carrier 102. Efficiency of the optoelectronic assembly 100 is reduced by these absorption losses.

FIG. 2 shows another example of a known optoelectronic assembly 100 in sectional view. Two optoelectronic components 104 are shown, which are arranged on a light-absorbing carrier 102. The optoelectronic component comprises a light-absorbing substrate 106. A part of the light 134 emitted by the light-emitting layer 108 is absorbed by the substrate 106 and the carrier 102. As previously shown in the example of FIG. 1, efficiency of the optoelectronic assembly 100 is reduced.

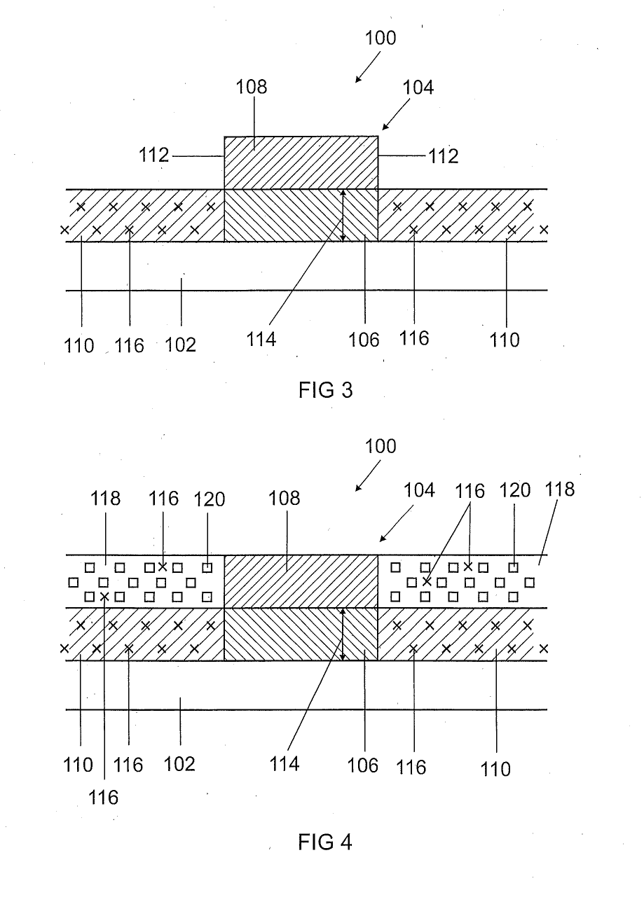

FIG. 3 shows an optoelectronic assembly 100 in sectional view. A single optoelectronic component 104 is arranged on a carrier 102. The optoelectronic component 104 comprises a substrate 106 on which a light-emitting layer 108 is arranged. A light-reflecting first encapsulation 110 fully covers the region of the carrier 102 surrounding the optoelectronic component 104 and locally covers the side surfaces 112 of the optoelectronic component 104. The carrier 102 may be a ceramic substrate. The ceramic substrate absorbs electromagnetic radiation. The conductor tracks on the ceramic substrate are not represented in FIG. 3. The substrate 106 may comprise aluminum nitride (AlN). Aluminum nitride absorbs electromagnetic radiation. The light-reflecting first encapsulation 110 has a height above the carrier 102 which corresponds to the thickness 114 of the substrate 106. The light-reflecting first encapsulation 110 comprises a matrix material filled with scattering particles 116. The matrix material may comprise silicone. The scattering particles 116 may comprise titanium dioxide. The scattering particles 116 may be present in a concentration of 5 percent by weight to 60 percent by weight.

FIG. 4 shows another optoelectronic component 100 in sectional view. This example is a refinement of the example of FIG. 3. A second encapsulation 118 is applied on the light-reflecting first encapsulation 110. The second encapsulation 118 ends flush, within the scope of manufacturing tolerance, with the edge of the light-emitting layer 108 facing away from the substrate 106. The second encapsulation 118 is filled with scattering particles 116 and luminescent particles 120. The scattering particles 116 may be present in a concentration of 0.001 percent by weight to 1 percent by weight. The luminescent particles 120 may be present in a concentration of 4 percent by weight to 30 percent by weight. The luminescent particles 120 may comprise yttrium aluminum garnet (Y₃Al₅O₁₂) and may convert blue light into yellow light.

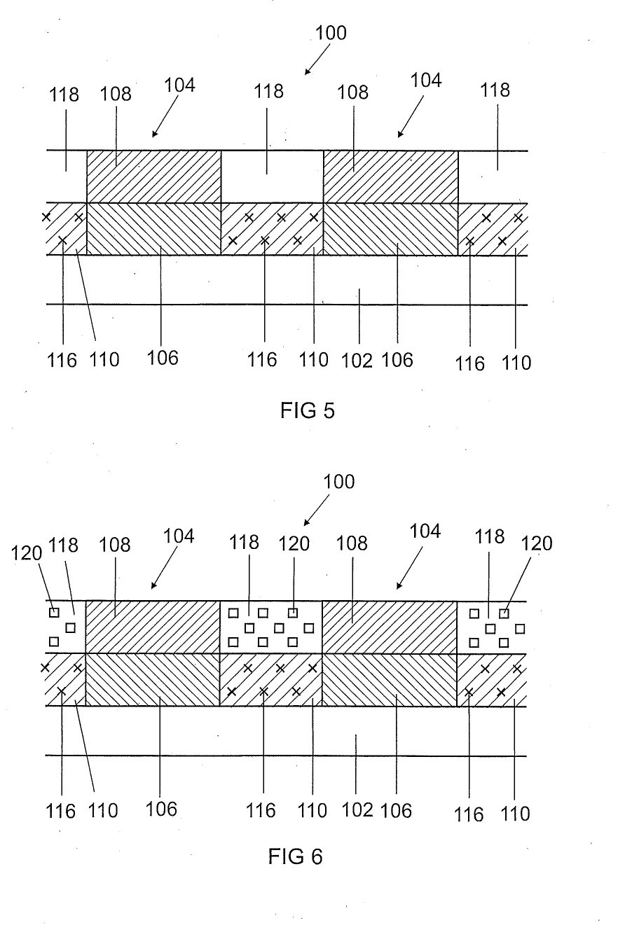

FIG. 5 shows an optoelectronic assembly 100 in sectional view. Two optoelectronic components 104 are arranged on a carrier 102. The distance between the neighboring optoelectronic components 104 is 0.1 mm to 1 mm, preferably 0.2 mm to 0.5 mm. The first encapsulation 110 covers the region of the carrier 102 not covered by the components and fully covers the side surfaces of the substrate 106. The scattering particles 116 are present in a high concentration, in particular 5 percent by weight to 60 percent by weight, in the light-reflecting first encapsulation 110. A second encapsulation 118 is applied onto the first encapsulation 110. The second encapsulation 118 is transparent. The second encapsulation 118 comprises unfilled matrix material, in particular comprising silicone. Light emitted laterally by the light-emitting layer 108 can enter the clear second encapsulation 118. In the clear second encapsulation 118, the light can propagate two-dimensionally and at least partially leave the second encapsulation 118. Consequently, the brightness difference between the light-emitting layers 108 and the second encapsulation 118 is reduced. The second encapsulation 118 in this case not only fills the gaps between the optoelectronic components 104, but also covers the region which surrounds the optoelectronic components 104. This example is particularly suitable for light-emitting layers 108 which only emit light of one color. The light-emitting layers 108 may comprise light-emitting semiconductor chips 122 (this is not shown in FIG. 5). Semiconductor chips 122 based on InGaN may emit primary light in the green and blue spectral range. Semiconductor chips 122 based on InGaAlP may emit primary light in the red to yellow spectral range.

FIG. 6 shows another optoelectronic assembly 100 in sectional view. In the example of FIG. 6, the second encapsulation 118 comprises luminescent particles 120. The luminescent particles 120 are present in a concentration of 4 percent by weight to 30 percent by weight in the matrix material comprising silicone. A part of the light entering the second encapsulation 118 laterally from the light-emitting layers 108 can be converted by the luminescent particles 120. For example, blue primary light may be converted into yellow secondary light. The blue primary light may be generated by a light-emitting semiconductor chip 122 based on InGaN (not shown in FIG. 6). Mixing blue primary light and yellow secondary light can give white light. In other words, the second encapsulation 118 shines white. The light-emitting layer 108 itself may likewise shine white. Here again, the white light may be generated by mixing blue primary light and yellow secondary light. A part of the blue primary light may in this case leave the light-emitting layer 108 without experiencing a wavelength change. A part of this blue primary light may then, as explained above, be converted into yellow light in the second encapsulation 118.

Since there are no lenses 304 arranged on the optoelectronic components 104, the possible emission angle is increased. Furthermore, the optoelectronic components 104 can be arranged closer together (distance 0.1 mm to 0.5 mm). In this way, higher luminous powers, a more homogeneous color distribution and a more homogeneous brightness distribution over the extent of the optoelectronic assembly 100 are possible.

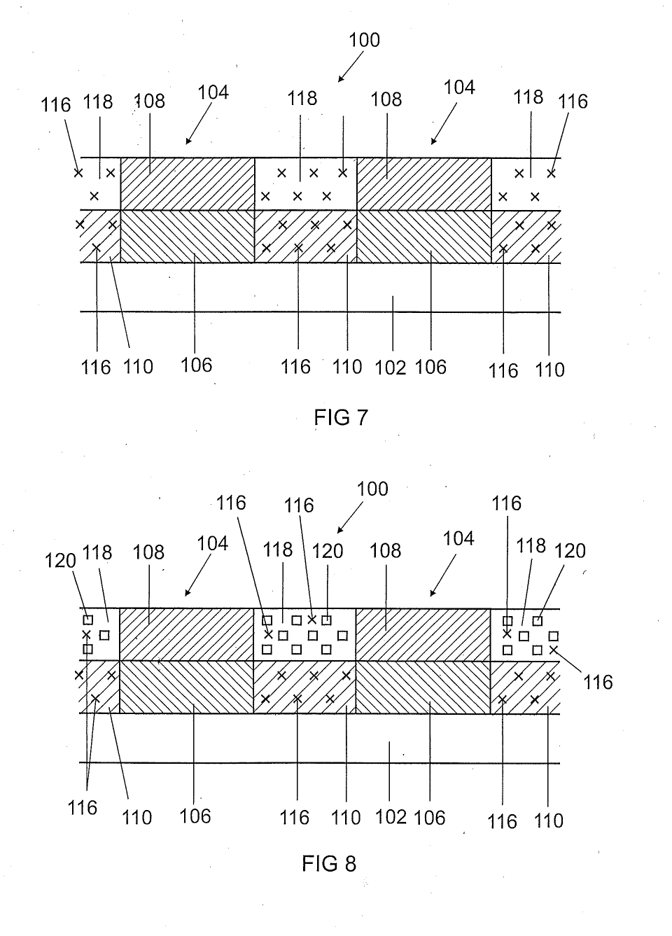

FIG. 7 shows another optoelectronic assembly 100 in sectional view. In the example of FIG. 7, the second encapsulation 118 has a low concentration of scattering particles 116. The concentration of the scattering particles in the matrix material is 0.001 percent by weight to 1 percent by weight. The matrix material may be silicone. Due to the low concentration of scattering particles 116, the second encapsulation 118 has only slightly diffuse optical properties. Light leaving the light-emitting layer 108 laterally and entering the second encapsulation 118 is mixed by the scattering particles 116. The light can be output over the entire surface of the second encapsulation 118. The light is distributed uniformly over the intermediate space between the optoelectronic components 104. Unlike in the first encapsulation 110 with the high concentration of scattering particles 116, light is scarcely reflected in the second encapsulation 118. Therefore, a large part of the light which has entered the second encapsulation 118 leaves the second encapsulation 118 after one or more scattering processes. The luminous density over the second encapsulation 118 is thereby increased. This example applies both for light-emitting layers 108 which emit light of one wavelength and for light-emitting layers 108 which emit white light.

FIG. 8 shows another optoelectronic assembly 100 in sectional view. In the example of FIG. 8, the second encapsulation 118 comprises both luminescent particles 120 and scattering particles 116. The luminescent particles 120 are present in the matrix material in a concentration of 4 percent by weight to 30 percent by weight. The scattering particles 116, as previously in the example of FIG. 7, are present in a low concentration of 0.001 percent by weight to 1 percent by weight. The effect of the combination of the luminescent particles 120 and scattering particles 116 is that light which enters the second encapsulation 118 from the light-emitting layer 108 is both converted and mixed. The undesired brightness contrast and the color contrast between the light-emitting layers 108 and the second encapsulation 118 can thereby be reduced significantly. In other words, the homogeneity with respect to brightness and color over the optoelectronic assembly 100 is increased.

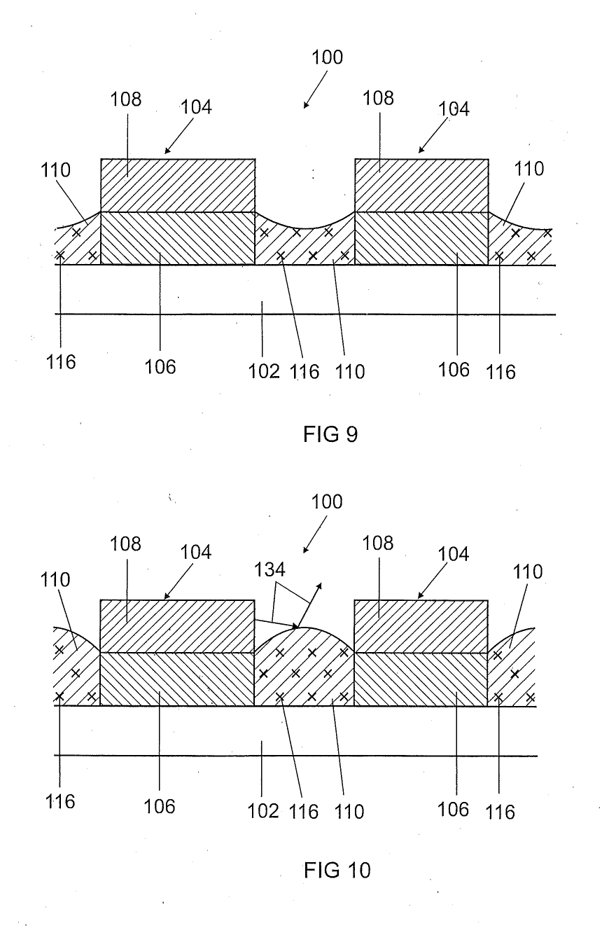

FIG. 9 shows an optoelectronic assembly 100 in sectional view. In the example of FIG. 9, the gap between the neighboring optoelectronic components 104 is encapsulated up to the height of the lower edge of the light-emitting layer 108 with a light-reflecting first encapsulation 110. The first encapsulation 110 has a high concentration of scattering particles 116. The surface of the first encapsulation 110 has a concave encapsulation. Centrally between the two optoelectronic components 104, the thickness of the first encapsulation 110 is less than directly at the optoelectronic components 104. The substrate 106 is in this case fully covered by the first encapsulation 110. The absorption losses are thereby reduced.

FIG. 10 shows an optoelectronic assembly 100 in sectional view. In the example of FIG. 10, in contrast to the example of FIG. 9, the light-reflecting first encapsulation 110 is encapsulated in a convex encapsulation. Centrally between the two optoelectronic components 104, the thickness of the first encapsulation 110 is greater than directly at the optoelectronic components 104. Light emerging laterally from the light-emitting layer 108 can strike the first encapsulation 110. Due to the high concentration of scattering particles 116 in the first encapsulation 110, the light is reflected at the first encapsulation 110.

FIG. 11 shows in detail an optoelectronic component 104 in sectional view. The optoelectronic component 104 comprises a light-emitting layer 108 applied on a substrate 106. The substrate 106 may comprise aluminum nitride. Aluminum nitride has a good thermal conductivity (170-230 W/(mK)) and is electrically insulating. The light-emitting layer 108 comprises a light-emitting semiconductor chip 122. The semiconductor chip 122 connects to the substrate 106 by bond pads 310. The electrical contact of the semiconductor chip 122 and the carrier 102 is established by electrically conductive vias 308 in conjunction with contacts 306. The semiconductor chip 122 is encapsulated in a third encapsulation 124, in particular comprising silicone. Luminescent particles 120 may be incorporated in the third encapsulation.

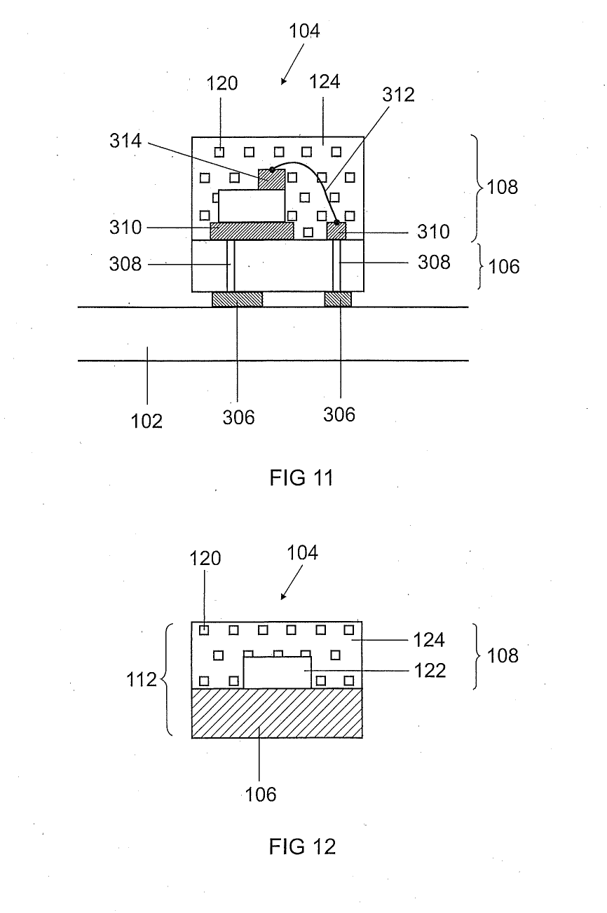

FIG. 12 shows the optoelectronic component 104 of FIG. 11 in a simplified and schematic way in sectional view. The light-emitting layer 108 has a semiconductor chip 122 encapsulated in a third encapsulation 124. The third encapsulation 124 may comprise luminescent particles 120.

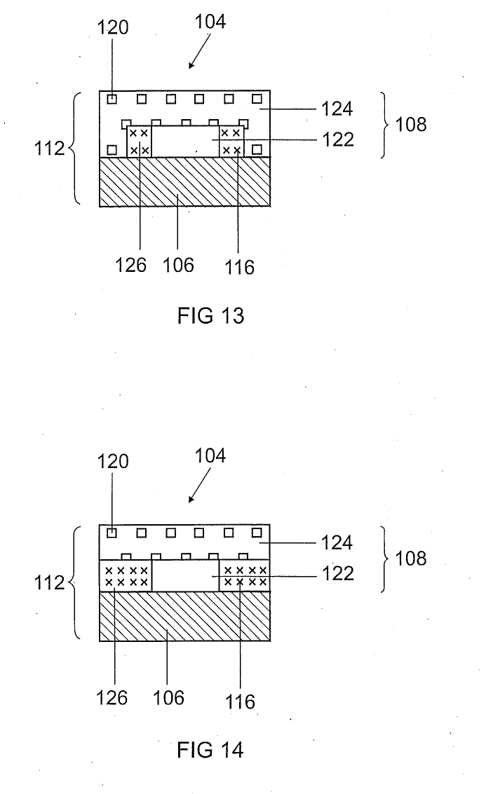

FIG. 13 schematically shows another example of the optoelectronic component 104. The semiconductor chip 122 is encapsulated on its side surfaces with a fourth encapsulation 126. Scattering particles 116 are incorporated in the reflective fourth encapsulation 126. The fourth encapsulation does not extend to the edge of the optoelectronic component 104.

FIG. 14 shows another example of the optoelectronic component 104. In contrast to the example of FIG. 13, the reflective fourth encapsulation 126 extends to the edge of the optoelectronic component 104. Due to the full coverage of the surface on which the semiconductor chip 122 is arranged, of the substrate 106 with the reflective fourth encapsulation 126, the unintended absorption of electromagnetic radiation by the substrate 106 is reduced. The fourth encapsulation 126 therefore increases the efficiency of the optoelectronic component 104.

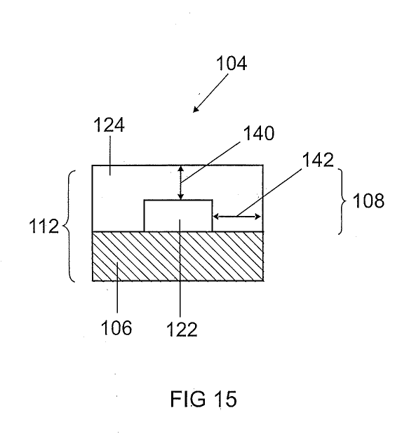

FIG. 15 shows another schematic representation of an optoelectronic component 104. The height 140 of the third encapsulation 124 above the light-emitting semiconductor chip 122 is indicated. The width 142 of the third encapsulation 124, as the distance from the side surface of the semiconductor chip 122 to the side surface 112 of the optoelectronic component 104, is furthermore indicated.

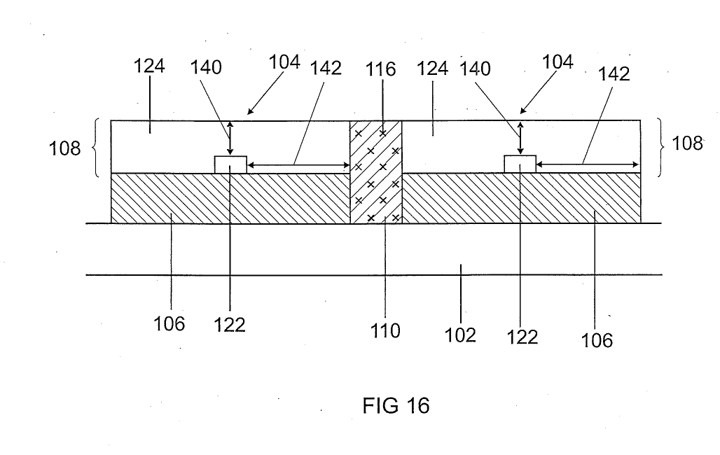

FIG. 16 shows an optoelectronic assembly 100 in sectional view. In the example of FIG. 16, wide optoelectronic components 104 are represented. Wide means that the width 142 is more than eight times as great as the height 140. As a consequence, the lateral emission of electromagnetic radiation into the gap between the two optoelectronic components 104 is reduced. The gap can therefore be fully filled with a first encapsulation 110 having a high concentration of scattering particles 116. The high reflectivity of the first encapsulation 110 is advantageous. The possibility of lateral output of the radiation generated in the light-emitting layer 108 is, however, not available.

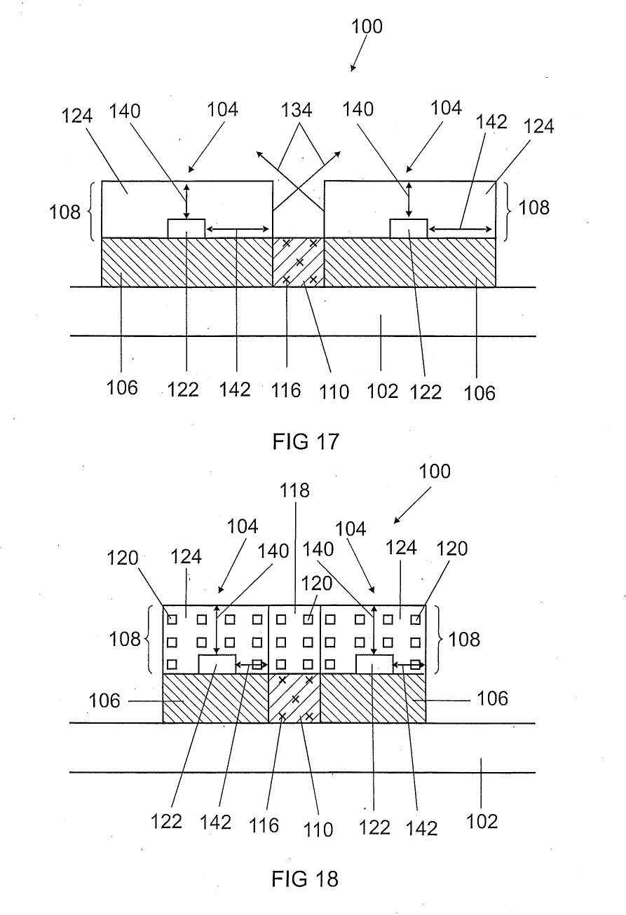

FIG. 17 shows an optoelectronic assembly 100 in sectional view. In the example of FIG. 17, narrow optoelectronic components 104 are represented. Narrow means that the width 142 is less than four times the height 140. As a consequence, there is strong lateral emission from the light-emitting layer 108. The gap between the two optoelectronic components 104 is encapsulated with a light-reflecting first encapsulation 110 only to the upper edge of the substrate 106. The side surfaces of the light-emitting layers 108 are exposed. An advantage is that a large part of the light 134 emitted by the light-emitting layers 108 can be output laterally.

FIG. 18 shows an optoelectronic assembly 100 in sectional view. In the example of FIG. 18, very narrow optoelectronic components 104 are represented. Very narrow means that the width 142 is less than the height 140. As a consequence, there is very strong lateral emission of light from the light-emitting layers 108. This assembly 100 is particularly suitable to generate white light. The second encapsulation 118 comprises luminescent particles 120. Without luminescent particles 120, the intermediate space between the optoelectronic components 104 would shine bluish. In the case of lateral emission, the blue primary radiation emitted by the semiconductor chip 122 travels a shorter path length in the third encapsulation 124 filled with luminescent particles 120 than in the case of perpendicular emission.

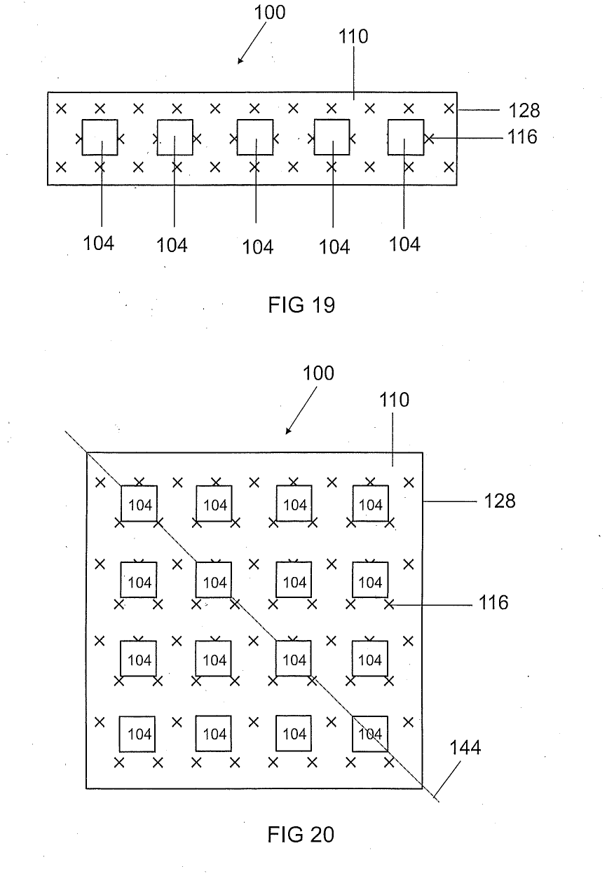

FIG. 19 shows an optoelectronic assembly 100 in plan view. A linear assembly of 5optoelectronic components 104 is shown. In examples not shown, up to 100 optoelectronic components 104 may be arranged linearly. The optoelectronic components 104 are laterally encapsulated fully with the light-reflecting first encapsulation 110, which has a high (up to 60 percent by weight) concentration of scattering particles 116. The region between the optoelectronic components 104 and the edge 128 of the optoelectronic assembly 100 is also fully encapsulated with the light-reflecting first encapsulation 110. The optoelectronic components 104 may emit light of one color or white light.

FIG. 20 shows an optoelectronic assembly 100 in plan view. A 2-dimensional assembly of 4 by 4 optoelectronic components 104 is shown. The shape of the optoelectronic assembly 100 is square. A section axis 144 is indicated. In examples not shown, up to 20 by 20 optoelectronic components 104 may be arranged.

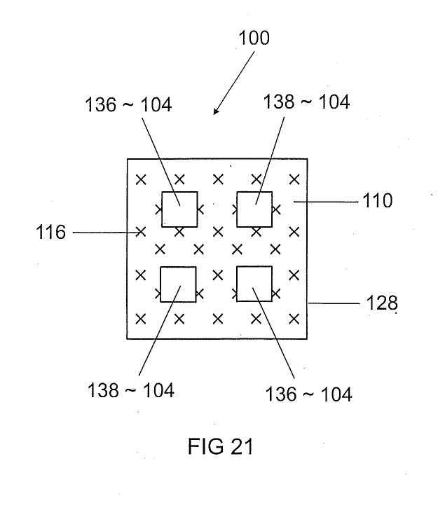

FIG. 21 shows an optoelectronic assembly 100 in plan view. A 2-dimensional assembly of 2 by 2 optoelectronic components 104 is shown. Two optoelectronic components 136 emitting amber-colored light, and two optoelectronic components 138 emitting mint-colored light, are represented in a square assembly 100. The mixture of amber-colored and mint-colored light gives white light. As previously shown in the examples of FIGS. 19 and 20, the optoelectronic components 104 are encapsulated in a light-reflecting first encapsulation 110.

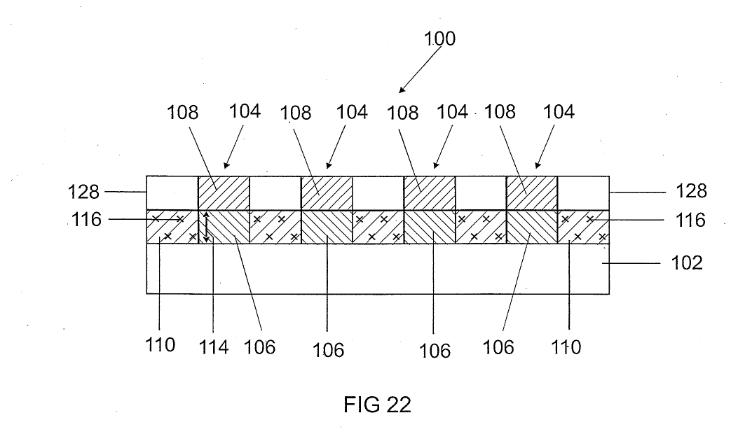

FIG. 22 shows an optoelectronic assembly 100 in sectional view. The sectional view shows the example of FIG. 20 along the section axis 144. 4 optoelectronic components 104 are shown, which are encapsulated with the light-reflecting first encapsulation 110 up to a height which corresponds to the thickness 114 of the substrate 106. The region between the optoelectronic components 104 and the edge 128 of the optoelectronic assembly 100 is also fully covered by the light-reflecting first encapsulation 110. The light-emitting layers 108 are exposed. This assembly 100 is particularly suitable for optoelectronic components 104 which emit light of one color.

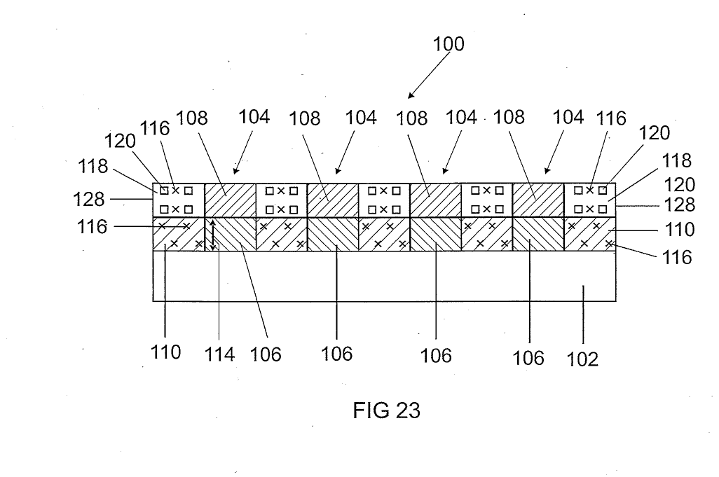

FIG. 23 shows an optoelectronic assembly 100 in sectional view. The example of FIG. 23 differs from the example of FIG. 22 insofar as a second encapsulation 118 is applied onto the light-emitting first encapsulation 110. The second encapsulation 118 fully covers the side surfaces of the light-emitting layers 108. The second encapsulation is filled with luminescent particles 120 and with scattering particles 116. The scattering particles 116 are present in a low concentration (0.001 percent by weight to 1 percent by weight). This assembly 100 is particularly suitable for optoelectronic components 104 which predominantly emit white light.

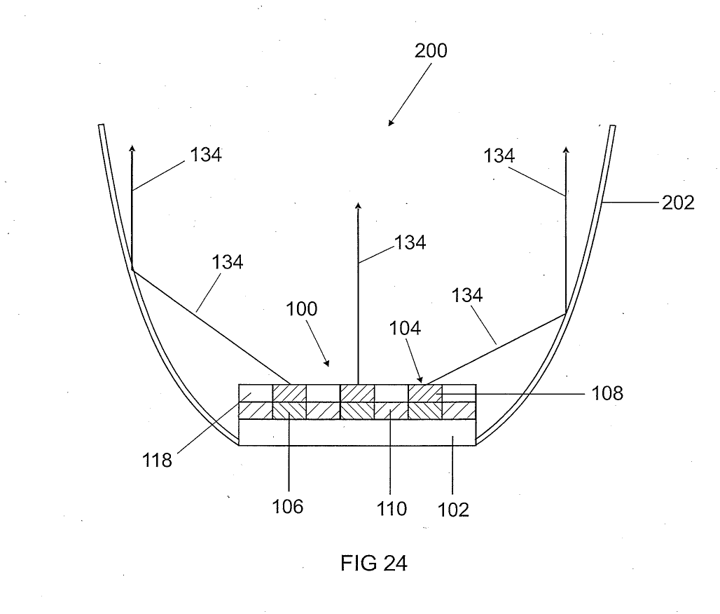

FIG. 24 shows a lighting device 200 having an optoelectronic assembly 100 and a secondary optical unit 202. The secondary optical unit 202 forwards the light 134 emerging from the optoelectronic assembly 100. In this case, the secondary optical unit 202 is a reflector. Light 134 which leaves the assembly 100 in a lateral direction can be reflected at the inner surface of the reflector and leave the lighting device in the forward direction. Both the light-emitting layers 108 and the second encapsulation 118 emit light. In this way, the contrast with respect to brightness and color between the light-emitting layers 108 and the second encapsulation 118 is reduced.

If a plurality of optoelectronic components 104 of a single color are combined in the optoelectronic assembly 100, the undesired multiple shadows are reduced particularly in the far field. The brightness differences between the optoelectronic components 104 and the region between the optoelectronic components 104 are blurred.

If a plurality of optoelectronic components 104 of different colors are combined in the optoelectronic assembly 100, the undesired color shadows are reduced particularly in the far field. For example, optoelectronic components 104 emitting red, green and blue may be combined.

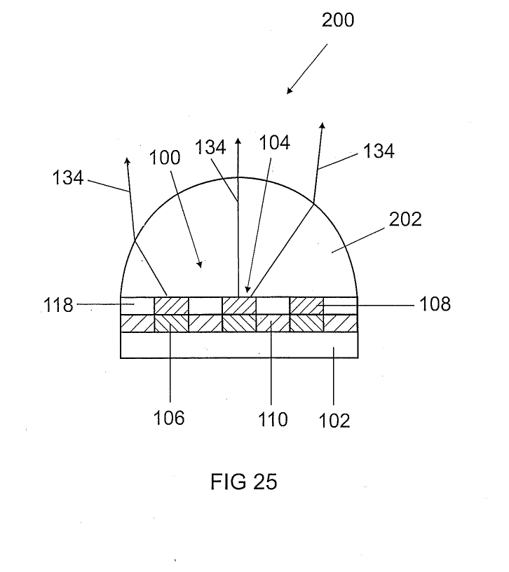

FIG. 25 shows a lighting device 200 having an optoelectronic assembly 100 and a secondary optical unit 202. The secondary optical unit 202 is a lens. By refraction of the light at the transition from the lens to air, as previously in the example shown in FIG. 24, the light 134 is emitted in the forward direction.

1-18. (canceled)

19. An optoelectronic assembly comprising:
a carrier,
an optoelectronic component arranged on the carrier,
wherein the optoelectronic component comprises a substrate and a light-emitting layer arranged on the substrate, and
a light-reflecting first encapsulation at least locally covers a region of the carrier surrounding the optoelectronic component and side surfaces of the optoelectronic component.

20. The optoelectronic assembly as claimed in claim 19, wherein the light-reflecting first encapsulation has a minimum height above the carrier corresponding to the thickness of the substrate.

21. The optoelectronic assembly as claimed in claim 19, wherein the light-reflecting first encapsulation comprises a matrix material filled with scattering particles, and the scattering particles are present in a concentration of 5 percent by weight to 60 percent by weight.

22. The optoelectronic assembly as claimed in claim 19, wherein a second encapsulation is applied at least locally on the first encapsulation.

23. The optoelectronic assembly as claimed in claim 22, wherein the second encapsulation ends flush, within the scope of manufacturing tolerance, with an edge of the light-emitting layer facing away from the substrate.

24. The optoelectronic assembly as claimed in claim 22, wherein the second encapsulation comprises a transparent, unfilled matrix material.

25. The optoelectronic assembly as claimed in claim 22, wherein the second encapsulation comprises a matrix material filled with scattering particles, and the scattering particles are present in a concentration of 0.001 percent by weight to 1 percent by weight.

26. The optoelectronic assembly as claimed in claim 22, wherein the second encapsulation comprises a matrix material filled with luminescent particles, and the luminescent particles are present in a concentration of 4 percent by weight to 30 percent by weight.

27. The optoelectronic assembly as claimed in claim 19, further comprising at least one further optoelectronic component arranged on the carrier.

28. The optoelectronic assembly as claimed in claim 27, wherein a distance between neighboring optoelectronic components is 0.1 mm to 1 mm.

29. The optoelectronic assembly as claimed in claim 19, wherein the light-emitting layer comprises a light-emitting semiconductor chip arranged on the substrate and is at least locally surrounded by a third encapsulation.

30. The optoelectronic assembly as claimed in claim 29, wherein the third encapsulation comprises a matrix material which is unfilled or comprises scattering particles and/or luminescent particles.

31. The optoelectronic assembly as claimed in claim 21, wherein the matrix material comprises at least one material selected from the group consisting of silicone, epoxy resin and hybrid materials.

32. The optoelectronic assembly as claimed in claim 21, wherein the scattering particles comprise at least one of titanium dioxide (TiO₂), aluminum oxide (Al₂O₃) or zirconium oxide (ZrO).

33. The optoelectronic assembly as claimed in claim 26, wherein the luminescent particles comprise at least one of lanthanum-doped yttrium oxide (Y₂O₃—La₂O₃), yttrium aluminum garnet (Y₃Al₅O₁₂), dysprosium oxide (Dy₂O₃), aluminum oxynitride (Al₂₃O₂₇N₅) or aluminum nitride (AlN).

34. The optoelectronic assembly as claimed in claim 19, wherein the carrier comprises one of a printed circuit board, a ceramic substrate, a metal core circuit board, a leadframe or a plastic laminate.

35. An optoelectronic assembly comprising:
a carrier,
an optoelectronic component arranged on the carrier,
wherein the optoelectronic component comprises a substrate and a light-emitting layer arranged on the substrate,
a light-reflecting first encapsulation at least locally covering a region of the carrier surrounding the optoelectronic component and side surfaces of the optoelectronic component, and
a second encapsulation applied at least locally on the first encapsulation, wherein the second encapsulation ends flush, within the scope of manufacturing tolerance, with an edge of the light-emitting layer facing away from the substrate.

36. The optoelectronic assembly as claimed in claim 35, further comprising at least one further optoelectronic component arranged on the carrier, wherein electromagnetic radiation emerges laterally from the light-emitting layers of the optoelectronic components.

37. A lighting device having an optoelectronic assembly as claimed in claim 19, wherein a second optical unit forwards light emerging from the optoelectronic assembly.

38. The lighting device as claimed in claim 37, wherein the secondary optical unit comprises at least one of a light guide, a scattering disk, a lens or a reflector.
